(19) United States
(12) Patent Application Publication
(10) Pub. No.: US 2026/0246224 A1
(43) Pub. Date: Aug. 20, 2026

(54) APPARATUS, SYSTEM AND METHOD FOR PROVIDING A LIGHT-MATTER INTERFACE FOR ENHANCING TRANSITIONS THAT GENERATE SINGLE PHOTONS

(71) Applicant: NU QUANTUM LTD, Cambridge (GB)

(72) Inventors: Laiyi WENG, Cambridge (GB); Bethany FOXON, Cambridge (GB); John PRENTICE, Cambridge (GB); Carmen PALACIOS-BERRAQUERO, Cambridge (GB)

(73) Assignee: NU QUANTUM LTD, Cambridge, CA (GB)

(21) Appl. No.: 18/705,548

(22) PCT Filed: Oct. 28, 2022
(86) PCT No.: PCT/GB2022/052745

§ 371 Date: Apr. 27, 2024

(30) Foreign Application Priority Data
Oct. 28, 2021 (GB) 2115541.1

(51) Int. Cl. H01S 3/1106; H01S 3/105; H01S 3/107

(52) U.S. Cl. CPC H01S 3/1106; H01S 3/105; H01S 3/107

(57) ABSTRACT

An apparatus, system and method for enhancing transitions that generate single photons through a light-matter interface is provided. The apparatus includes a first reflective surface, and a locking and emitting recess within respective reflective surfaces. The locking and emitting recesses form a locking cavity and an emitting cavity, respectively. The locking cavity receives light from a locking laser, with output light indicating resonance with the laser. The emitting cavity receives photons from a single photon emitter material, which emits single photons upon excitation. An actuator adjusts length of the locking cavity based on the single photon output to maintain resonance, thereby locking the cavity. Both reflective surfaces are mechanically coupled by a same substrate, aligning the locking of the locking cavity with the tuning and stabilization of the emitting cavity at the single photon emission wavelength. The apparatus ensures enhanced efficiency and stability in single photon generation.

### TECHNICAL FIELD

The present disclosure relates to an apparatus, system and method for providing a light-matter interface for enhancing transitions that generate single photons and a method of manufacturing such an apparatus. In particular, the disclosure relates to an apparatus including a single photon emitter material, such as a solid state material, a trapped ion or neutral atom, arranged in an optical cavity. The disclosure finds utility in, for example, providing sources of single photons, or for interfacing with and manipulating quantum objects, such as qubits in a quantum computer.

### BACKGROUND

Sources of single photons are expected to be essential to a range of near-future applications such as quantum computing and information processing, cryptography and communication.

A number of possible sources that could be used to generate single photons have been investigated, including single emitters such as trapped ions and single atoms, solid state emitters including quantum dots, colour centres in solids, or heralded single photon sources such as spontaneous parametric downconversion. Fluorescent quantum defects, such as optically active quantum dots of tightly confined electrons or holes in semiconductor materials, capable of being excited to then decay and emit single photons, can be formed in solid state three dimensional material such as defects in diamond, or by epitaxial growth of layers having lattice constant mismatches at their interface, such as in InGaAs quantum dots in GaAs. Such quantum defects have also been shown to be created in two-dimensional materials such as graphene and tungsten diselenide, in which atoms form crystalline structures in monolayers or low numbers of multilayers, with quantum dots occurring naturally in particular at the edges of the material, or with quantum dots being artificially formed using a variety of engineering techniques. Such quantum dots in two-dimensional materials naturally have an out-of-plane emission, which facilitates the collection and use of the single photons, and such materials are typically robust and can be easily integrated into photonic devices.

The effectiveness of such material as a source of single photons for these applications depends on whether they can be harnessed to stably, reliably and easily produce pure and indistinguishable single photons in large numbers and at a suitably high emission rate. Further, the ability to operate these single photon sources without requiring cryogenic cooling, and the ability to manufacture such sources at scale to a consistent quality and performance, would facilitate their adoption and enable the development of quantum computing and information processing technologies.

Single photons can also emitted by quantum objects, such as trapped ions and neutral atoms, which may be used as physical qubits, for example in a quantum computer. In this case, the physical qubit acts as a single photon generating material. Transitions that emit single photons from these quantum objects can provide a mechanism for interfacing with the physical qubits to manipulate or interrogate them. However, these transitions to generate single photons do not reliably occur at a sufficiently high rate.

The present disclosure has been devised in the foregoing context.

### SUMMARY

Viewed from one aspect, the present disclosure provides an apparatus for generating single photons. In particular, the apparatus may be considered to provide a light-matter interface for enhancing transitions that generate single photons. The apparatus comprises: a first reflective surface; a locking recess formed in a locking reflective surface, the first reflective surface and locking recess forming a locking cavity to receive light from a locking laser, the portion of light output from the locking cavity indicative of whether the locking cavity is on resonance with the locking laser; an emitting recess formed in an emitting reflective surface, the first reflective surface and emitting recess forming an emitting cavity to receive photons from a single photon emitter material, the single photon emitter material located in the emitting cavity to emit single photons in response to optical or electrical excitation of the material; and an actuator to tune the length of the locking cavity based on the portion of light output from the locking cavity to be on resonance with the locking laser to lock the locking cavity to the locking laser, wherein the locking reflective surface and emitting reflective surface are mechanically coupled such that locking the locking cavity tunes and stabilises the emitting cavity at a single photon emission wavelength.

Viewed from another aspect, the present disclosure provides a method for generating single photons. In particular, the method may be considered to provide a light-matter interface for enhancing transitions that generate single photons. The method comprises: receiving light at a locking cavity from a locking laser, the locking cavity formed from a first reflective surface and a locking recess formed in a locking reflective surface, the portion of light output from the locking cavity indicative of whether the locking cavity is on resonance with the locking laser; tuning the length of the locking cavity based on the portion of light output from the locking cavity to be on resonance with the locking laser to lock the locking cavity to the locking laser; and emitting, by single photon emitter material located in an emitting cavity, single photons in response to optical or electrical excitation of the material, the emitting cavity formed from the first reflective surface and an emitting recess formed in an emitting reflective surface; wherein the locking reflective surface and emitting reflective surface are mechanically coupled such that locking the locking cavity tunes and stabilises the emitting cavity at a single photon emission wavelength.

In accordance with the above aspects of the disclosure, a single photon emitting material is provided coupled in an optically resonant cavity to enhance emission and raise the photon generation efficiency thereof, wherein a separate mechanically coupled locking cavity is provided that can be used, in conjunction with an appropriate stable laser, to control the actuator to maintain the locking cavity on resonance with the stable laser, using an appropriate locking technique. By maintaining the locking cavity optically tuned to a stable laser, the mechanically coupled emitting cavity containing the single photon emitting material can also be maintained in a stable tuning, which may be configured to be resonant with an emission wavelength of the single photon emitting material, such as a zero phonon line thereof, allowing suppression of a phonon side-band thereof. In this way, apparatuses in accordance with the above aspect of the disclosure, can be controlled to maintain long term emission cavity mode stability at the single photon emission wavelength. Moreover, as the single photon emitting material can be maintained in a stable tuning using the locking cavity mechanically coupled to the emitting cavity, the apparatus does not require a specific single photon emitting material because the locking cavity, and consequently the tuning, can be adjusted based on the material. Further, as the tuning of the locking cavity tunes the emission cavity through a mechanical coupling in the apparatus, the locking cavity can be tuned using light that is separate from the emission cavity, meaning that the light from the locking laser is decoupled from the photons from the single photon emitter. That is, the light from the locking laser can be used to tune the emitting cavity used to enhance the emission of single photons from the material, without it entering the emitting cavity, or needing to be separated from the emitted single photons. Thus the apparatus can be used to reliably generate a stable source of indistinguishable photons from a suitable single photon emitting material.

In embodiments, the portion of light output from the locking cavity may be the portion of light reflected and/or transmitted from the locking cavity. The mode locking of the cavity may be conducted using the portion of light reflected from the cavity or the portion of light transmitted through the cavity, although performance may be better using reflected light.

In embodiments, the locking reflective surface and emitting reflective surface may be mechanically supported by the same substrate. For example, the locking reflective surface and emitting reflective surface may be provided in a surface of the same substrate, such as being formed in the same substrate layer using an appropriate technique, such as focussed ion beam (FIB) milling or CO2 laser processing. Alternatively, the locking reflective surface and emitting reflective surfaces may be provided in different layers of the substrate, or in layers of material deposited on or fixed to the substrate, or in recessed surfaces formed in the substrate, for example by etching. Nevertheless, the locking reflective surface and emitting reflective surfaces may be supported by the same substrate. In embodiments, the locking reflective surface and emitting reflective surface may be on different substrates. In embodiments, the substrate comprising the emitting reflective surface may be mechanically coupled to the locking reflective surface of the substrate comprising the locking reflective surface. In embodiments, the emitting recess and locking recess may have different depths. In embodiments, the locking reflective surface and emitting reflective surface may be at different distances from the first reflective surface, such that the locking cavity has a different length to the emitting cavity. For example, the locking cavity may have a longer length than the emitting cavity. The locking reflective surface and emitting reflective surface may have different depths in the substrate or may be formed at different heights. This allows the locking laser to be decoupled from the single photon emission. By allowing the locking cavity to be formed to have different coupling characteristics to the emitting cavity, this allows the locking cavity to be optimised for a given mode locking technique, and the emitting cavity to be optimised for matching the resonant wavelength of the single photon emission, while also allowing the tuning of the locking cavity to lead to the tuning of the emitting cavity.

In embodiments, the emitting cavity may be to receive light from an excitation laser and the single photon emitter material may be to emit single photons in response to the received light from the excitation laser being incident on the material. In this way, the single photon emitting material in the cavity can be stimulated to emit a single photon. The single photon emitting material may be any material capable of emitting single photons in response to stimulation.

In embodiments, the emitter cavity and the locking cavity may be laterally spaced and substantially axially aligned. In this way, the tuning of the locking cavity by the actuator can also tune the emitting cavity, while the locking cavity is separated from the emitting cavity, such that the locking laser light enters the locking cavity and not the emitting cavity. In embodiments, the locking cavity and emitting cavity may operate in different modes and may have different resonant wavelengths. In this way, the locking laser light would not be resonant with the emitting cavity and would be transmitted through it.

In embodiments, the emitting cavity may have a length in the range 0.3-10 μm and the locking cavity may have a length in the range 10-1000 μm. In embodiments, the emitting cavity may have a line width in the range 10-1000 GHz and the locking cavity may have a line width in the range 10-1000 MHz. In this way, the locking cavity may be optimised for use as a locking cavity using the Pound Drever Hall (PDH) technique, in which the locking cavity line width is lower than the emitting cavity line width, and in which the locking laser light is phase modulated using an electro optic modulator at a frequency significantly greater than the locking cavity line width, for example in the GHz range. Alternatively, the locking cavity may be optimised for use as a locking cavity using the side-locking technique, in which the locking reference is set to the steepest part of the side of the cavity mode and intensity change is monitored as the cavity mode drifts off the set point. This intensity change is then used to correct for frequency drift.

In embodiments, the apparatus may operate in a temperature range between 4K and room temperature. The cavity locking mechanism provided by the locking cavity and emitting cavity can operate at any temperature as it is temperature-insensitive. The temperature range of the apparatus may depend on the single photon emitter material used. Moreover, whilst the apparatus may operate within a particular temperature range, the chosen temperature at which to operate the apparatus may be the temperature at which the apparatus is most effective, that is, at which the apparatus most reliably generates a stable source of indistinguishable photons. For example, the apparatus may operate at a low temperature, for example below 0° C., in order to achieve particular performance metrics.

In embodiments, the single photon emitter material may be a two dimensional material having a fluorescent defect or a quantum dot. In embodiments, the single photon material may be to emit single photons at temperatures in the range 0-20° C. In embodiments, the single photon emitter material may comprise hexagonal Boron Nitride, hBN. Where the single photon emitter material is hBN, this enables the apparatus to operate in the temperature range of 0-20° C. Whilst hBN also emits single photons at a much larger range of temperatures than the range 0-20° C., and so the apparatus can operate at a large range of temperatures including temperatures significantly lower than 0-20° C., being able to emit photons at room temperature increases the usefulness of the material. In other embodiments, the single photon emitter material may comprise nanodiamond or layered transition-metal dichalcogenides. In other embodiments, the single photon emitter material may comprise a trapped ion or neutral atom, or a quantum object. In embodiments, the single photon emitter material may be a quantum object, for example a qubit in a quantum computer.

In embodiments, the single photons emitted from the single photon emitter material may have a wavelength of approximately 400 nm or above. For example, the single photons emitted from the single photon emitter material may have a wavelength of between 550 nm and 800 nm.

In embodiments, tuning the length of the locking cavity may comprise adjusting the first reflective surface and/or the locking reflective surface. In embodiments, the actuator may be a piezo actuator. In embodiments, the actuator may be to tune the length of the locking cavity based on the phase of the portion of light output from the locking cavity. In embodiments, the locking cavity and emitting cavity may be Fabry-Perot cavities. In embodiments, the locking cavity may be to receive light from the locking laser that has been modulated in phase. In this way, the actuator may fine tune the length of the locking cavity to lock it to the stable locking laser. In embodiments, the actuator may actuate a portion of the apparatus providing the first reflective surface, a portion of the apparatus providing the locking reflective surface and/or a portion of the apparatus providing the emitting reflective surface.

Viewed from another aspect, the present disclosure provides a system for generating single photons. In particular, the system may be considered to provide a light-matter interface for enhancing transitions that generate single photons. The system comprising: an apparatus for generating single photons in accordance with aspects of the present disclosure; and optics for transmitting light into the locking cavity of the apparatus.

In embodiments, the optics may comprise a locking laser to generate light for transmission into the locking cavity of the apparatus. In embodiments, the locking laser may be to generate light having a wavelength different to that of the single photon emission wavelength. In embodiments, the optics may further comprise a modulator to modulate the phase of the light generated by the locking laser and transmit the modulated light into the locking cavity of the apparatus. In embodiments, the modulator may be an electro optic modulator. In embodiments, the system may further comprise an RF driver coupled to the electro optic modulator and configured to output a modulation signal to drive the modulator to modulate the phase of the locking laser at a phase modulation frequency substantially greater than the linewidth of the locking cavity. In embodiments, the phase modulation frequency may be at least 1 GHz. In embodiments, the optics may further comprise a coherent detector to detect the portion of light output from the locking cavity of the apparatus and mix the detected light signal with the modulation signal from the RF driver to output a feedback signal based on the detected portion of light indicative of the drift of the locking cavity from the locking laser. In embodiments, the system may further comprise a controller configured to receive the feedback signal and output an error signal to the actuator of the apparatus based on the feedback signal, the actuator to tune the length of the locking cavity based on the error signal to maintain the locking cavity on resonance with the locking laser. In embodiments, the controller may be to output the error signal to the actuator of the apparatus based on the phase of the detected portion of light output from the locking cavity. In embodiments, the controller may be a proportional integral derivative (PID) controller. In embodiments, the system may be configured to control the actuator to lock the locking cavity to being on resonance with the locking laser using a Pound Drever Hall technique. In embodiments, the system may be configured such that the locking of the locking cavity to being on resonance with the locking laser causes a fundamental mode of the emitter cavity to be maintained on resonance with single photon emission frequency of the single photon emitter material. In embodiments, the system may further comprise a pulsed excitation laser and optics to direct light from the pulsed excitation laser to illuminate the single photon emitter material in the emitter cavity to trigger the emission of single photons at the fixed single photon emission frequency. In this way, the apparatus may be operated to maintain the single photon emitting material in an enhancement cavity at a stable long term frequency held on resonance with the single photon emitting frequency, without the locking laser light being coupled or mixed with the single photons, facilitating their detection.

In embodiments, the system may further comprise at least one further apparatus for generating single photons in accordance with aspects of the present disclosure. In embodiments, the optics may be configured to transmit light into the locking cavities of each of the apparatuses from the same locking laser. In embodiments, the optics may be further configured to transmit light into the emitting cavities of each of the apparatuses from the same pulsed excitation laser, the photon emitter material of each apparatus to emit single photons in response to the received light from the excitation laser being incident on the material. In embodiments, the plurality of emitter cavities in the plurality of apparatuses may be for emitting single photons, each emitter cavity emitting single photons at substantially the same fixed single photon frequency responsive to illumination by an excitation laser. In this way, a plurality of single photon emitters provided in separate, tuneable, apparatuses, may all be tuned together to stay on resonance long term with their single photon emission wavelengths based on the same, common, stable locking laser.

Viewed from another aspect, the present disclosure provides a method of manufacturing an apparatus for generating single photons, the method comprising: providing a locking substrate comprising a locking reflective surface; forming a recess in the locking reflective surface to form a locking cavity with a first reflective surface of a first substrate; providing an emitting substrate comprising an emitting reflective surface, the emitting substrate and locking substrate being mechanically coupled; forming a recess in the emitting reflective surface to form an emitting cavity with the first reflective surface of the first substrate; providing a single photon emitter material for emitting single photons located in the emitting cavity; providing the first substrate comprising the first reflective surface; and tuning the length of the locking cavity based on the cavity length of the locking cavity to tune the length of the emitting cavity into a fixed configuration, to be fine tuned by an actuator during use. In embodiments, the recesses may be formed using a focused ion beam.

Many modifications and other embodiments of the inventions set out herein will come to mind to a person skilled in the art to which these inventions pertain in light of the teachings presented herein. Therefore, it will be understood that the disclosure herein is not to be limited to the specific embodiments disclosed herein. Moreover, although the description provided herein provides example embodiments in the context of certain combinations of elements, steps and/or functions may be provided by alternative embodiments without departing from the scope of the invention.

### BRIEF DESCRIPTION OF THE DRAWINGS

Embodiments of the invention will now be described, by way of example only, with reference to the accompanying drawings in which like reference numerals are used to depict like parts. In the drawings:

FIG. 1 shows a schematic illustration of an apparatus for generating single photons in accordance with aspects of the present disclosure;

FIG. 2A shows a first embodiment of an apparatus for generating single photons in accordance with aspects of the present disclosure;

FIG. 2B shows a second embodiment of an apparatus for generating single photons in accordance with aspects of the present disclosure;

FIG. 3 shows a schematic illustration of an embodiment of a system for use in generating single photons in accordance with aspects of the present disclosure;

FIGS. 4A and 4B show further schematic illustrations of other embodiments of a system for generating single photons in accordance with aspects of the present disclosure;

FIG. 5 shows a further schematic illustration of another embodiment of a system for generating single photons in accordance with aspects of the present disclosure;

FIG. 6 shows a method for generating single photons in accordance with aspects of the present disclosure;

FIG. 7 shows a method of manufacturing an apparatus for generating single photons in accordance with aspects of the present disclosure;

FIG. 8A shows a third embodiment of an apparatus for generating single photons in accordance with aspects of the present disclosure;

FIG. 8B shows a fourth embodiment of an apparatus for generating single photons in accordance with aspects of the present disclosure.

### DETAILED DESCRIPTION

Hereinafter, embodiments of the disclosure are described with reference to the accompanying drawings. However, it should be appreciated that the disclosure is not limited to the embodiments, and all changes and/or equivalents or replacements thereto also belong to the scope of the disclosure. The same or similar reference denotations may be used to refer to the same or similar elements throughout the specification and the drawings.

As used herein, the terms “have,” “may have,” “include,” or “may include” a feature (e.g., a number, function, operation, or a component such as a part) indicate the existence of the feature and do not exclude the existence of other features.

As used herein, the terms “A or B,” “at least one of A and/or B,” or “one or more of A and/or B” may include all possible combinations of A and B. For example, “A or B,” “at least one of A and B,” “at least one of A or B” may indicate all of (1) including at least one A, (2) including at least one B, or (3) including at least one A and at least one B.

As used herein, the terms “first” and “second” may modify various components regardless of importance and do not limit the components. These terms are only used to distinguish one component from another. For example, a first user device and a second user device may indicate different user devices from each other regardless of the order or importance of the devices. For example, a first component may be denoted a second component, and vice versa without departing from the scope of the disclosure.

It will be understood that when an element (e.g., a first element) is referred to as being (mechanically, operatively or communicatively) “coupled with/to,” or “connected with/to” another element (e.g., a second element), it can be coupled or connected with/to the other element directly or via a third element. In contrast, it will be understood that when an element (e.g., a first element) is referred to as being “directly coupled with/to” or “directly connected with/to” another element (e.g., a second element), no other element (e.g., a third element) intervenes between the element and the other element.

As used herein, the terms “configured (or set) to” may be interchangeably used with the terms “suitable for,” “having the capacity to,” “designed to,” “adapted to,” “made to,” or “capable of” depending on circumstances.

It is to be understood that the singular forms “a,” “'an,” and “the” include plural references unless the context clearly dictates otherwise.

The terms as used herein are provided merely to describe some embodiments thereof, but not to limit the scope of other embodiments of the disclosure. All terms including technical and scientific terms used herein have the same meaning as commonly understood by one of ordinary skill in the art to which the embodiments of the disclosure belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used throughout the Figures, features or method steps are shown outlined in broken lines to indicate that such features or method steps are optional features for provision in some embodiments, but which are not provided in all embodiments to implement aspects of the disclosure. That is, aspects of the disclosure do not require these optional features to be included, or steps to be performed, and they are merely included in illustrative embodiments to provide further optional implementation details.

With reference now to the figures, FIG. 1 shows a schematic illustration of an apparatus 100 for generating single photons in accordance with aspects of the present disclosure. The apparatus 100 includes a single photon emitter material 112 (which may also be referred to as a quantum emitter material) for generating single photons in use in response to optical or electrical excitation thereof. For example, light from an excitation laser may be transmitted into the cavity to illuminate and optically excite the single photon emitter material 112 to trigger photons to be emitted by the material 112 at a single photon emission frequency. An example excitation laser input is illustrated by the dashed arrow in FIG. 1. The single photon emission frequency may be a fixed frequency or the single photon emitter material 112 may be tuneable to emit photons at a particular frequency. The single photon emitter material 112 may be any material for generating single photons as a result of, for example, energy level transitions. For example, the single photon emitter material 112 may be a solid state material for generating single photons, or a quantum object such as a trapped ion or neutral atom serving as a qubit in a quantum computer for example. Where the single photon emitter material 112 is a solid state material, it may be a low dimensional material or a membrane with a thickness less than ten micrometres. In the embodiment, the single photon emitter material 112 is a two dimensional material of one or a few layers of atoms grown in a crystalline structure, containing one or more fluorescent defects. The two dimensional single photon emitter material 112 may be hexagonal Boron Nitride (hBN), which has a large band gap between the valence band and conduction band, giving a transition energy for the fluorescent defect that allows single photon emissions at a peak emission wavelength (corresponding to a zero phonon line thereof) that is resolvable from a phonon sideband (PSB) thereof. For hBN, the energy levels introduced into the band structure are well isolated and the large bandgap also aids in preventing Auger-type non-radiative decay, improving the quantum efficiency of hBN emitters. The two dimensional structure of hBN also allows for intrinsically high extraction efficiency as the emitted photons are not affected by total internal or Fresnel reflection. The single photon emitter material 112 may be a hBN flake chosen to have a peak emission wavelength at or close to a desired wavelength. The single photon emitter material 112 may be formed from a single layer or multiple layers of hBN flakes. The single photon emitter material 112 may be an exfoliated hBN flake, CVD-grown hBN or a solution based hBN flake. One advantage of hBN is that it allows single photon emissions at room temperature, in the region of 0 -20 degrees Celsius, and so an apparatus comprising hBN is operable at room temperature.

In the apparatus 100, the single photon emitter material 112 is provided in an optically resonant emitting cavity 106 (which may also be referred to as an interface cavity or science cavity) formed between a first reflective surface 102 and an emitting reflective surface 104, with the fluorescent defect of the single photon emitter material 112 being aligned in the emitting cavity 106 to be optically coupled therewith when the emitting cavity 106 is on resonance with the emission wavelength of the fluorescent defect. The single photon emitter material may be located on the first reflective surface 102 as this location allows for greater control of the cavity to facilitate alignment, and provides the strongest electric field. The emitting cavity 106 may be arranged as a Fabry Perot-type cavity, with a plano-concave structure, with the first reflective surface 102 having a planar mirrored surface with a very high reflection coefficient in the wavelength of interest in the region of 99.9%, and the emitting reflective surface 104 being formed to have a concave mirrored surface with a very high reflection coefficient in the wavelength of interest in the region of 99.99%. The single photon emitter material 112 is located in the emitting cavity 106 aligned such that the fluorescent defect is on resonance therewith when excited, and is held in place by any appropriate locating means, such as by adhesion to the emitting reflective surface 104 by Van der Waals forces. One advantage of using a two dimensional material as the single photon emitter material 112 is that Van der Waals forces can be used to easily attach the crystals to a surface.

The apparatus 100 is such that, when the emitting cavity 106 is tuned to be at a stable resonant frequency aligned with the peak emission wavelength of the single photon emitter material 112, the photon generation efficiency by the fluorescent defect is increased by the Purcell effect, decreasing the decay lifetime of the fluorescent defect from its excited state, such that the emission of single photons out of the cavity, for use in a range of quantum computing, information processing, or communication applications, is enhanced. Further, the apparatus 100 is such that, when the emitting cavity 106 is tuned to be at a stable resonant frequency aligned with the peak emission wavelength of the single photon emitter material 112, the phonon sideband (PSB) is fully suppressed leading to the single photon emitter material 112 coupling more energy into the single photon emission. Other off-resonant noise is also fully supressed. Thus, the provision of the single photon emitter material 112 in the emitting cavity 106 enables high-level control of the single photons emitted out of the cavity with enhanced optical properties including improved spectral purity.

To allow the emitter cavity 106 to be actively tuned to stay on resonance with the single photon emitter material 112 to compensate for a range of environmental factors, such as temperature variation, an actuator 114, such as a piezoelectric transducer, is used to actuate the mechanical structure supporting the emitting cavity 106 to fine tune the length of the emitting cavity 106. However, the amount of tuning required needs to be determined. One way of detecting the amount of tuning required is to transmit light from a locking laser into the emitting cavity 106, where the portion of light from the locking laser that is output from the emitting cavity 106 would indicate the amount of tuning required by the actuator 114. However, due to the same cavity performing both locking and emission, the light from the locking laser and the photons emitted from the single photon emitter material 112 would interfere as the locking laser would lead the cavity mode onto the single photon emission such that there would be frequency overlap between the locking frequency of the locking laser and the single photon emission frequency. This would reduce the output intensity and thus the effectiveness of the single photon emitter. For such interference to be reduced, sophisticated polarisation would be required which would be expensive and complex. Another way of detecting the amount of tuning required is to use the single photons to determine the amount of tuning required rather than a locking laser. However, the photon intensity would be unstable and these photons would then be wasted, and such a design would therefore also reduce the output intensity of the single photon emitter.

To provide a more stable single photon emitter with increased output intensity, as illustrated in FIG. 1, the apparatus 100 of the present disclosure includes a locking cavity 110 mechanically coupled to the emitting cavity 106. The use of the locking cavity 110 to sense a tuning signal can be used to control the actuator 114 such that the locking cavity 110, and the mechanically coupled emitting cavity 106, are maintained to have a steady length and resonant frequency. The apparatus can be configured such that, by tuning the locking cavity 110, the emitting cavity 106 can be tuned to be on resonance with the peak emission wavelength of the single photon emitter material 112. Thus, by actuating the mechanical structure supporting both the emitting cavity 106 and locking cavity 110, the actuator 114 can tune the length of the locking cavity 110 to lock the locking cavity 110 to the locking laser which in turn tunes and stabilises the emitting cavity 106 at the single photon emission wavelength, which is the wavelength of the single photons output from the emitting cavity 106 by the single photon emitter material 112. The emission of the singe photons from the emitter cavity 106 is illustrated by the unbroken arrow in FIG. 1.

The locking cavity 110 is formed between the first reflective surface 102 and a locking reflective surface 108. Thus, the locking cavity 110 and emitting cavity 106 share a first reflective surface 102. The locking cavity 110 may also be arranged as a Fabry Perot-type cavity, with a plano-concave structure, with the locking reflective surface 108 being formed to have a concave mirrored surface with a very high reflection coefficient in the wavelength of interest in the region of 99.9%.

The addition of the locking cavity 110 enables tuning of the emitting cavity 106. The actuator 114 is controlled to maintain the fundamental mode of the locking cavity on resonance with a stable locking laser, using an appropriate locking technique. As indicated by the dotted arrows in FIG. 1, the locking cavity 110 may receive light from the locking laser, where the portion of light from the locking laser that is output, for example transmitted or reflected, from the locking cavity 110 indicates whether the locking cavity is on resonance with the locking laser. The wavelength of the locking laser may differ to the single photon emission wavelength. Where the locking cavity is not on resonance with the locking laser, the portion of light from the locking laser that is output from the locking cavity 110 may indicate the difference between the frequency of the locking laser and the resonant frequency of the locking cavity. The actuator 114 is to adjust the mechanical structure supporting the locking cavity 110 based on the portion of light output from the locking cavity 110 to tune the length of the locking cavity to move the locking cavity on resonance with the locking laser to lock the locking cavity to the locking laser. For example, the actuator 114 may actuate the first reflective surface 102 and/or locking reflective surface 108, moving them towards or away from each other to adjust the spacing between them. By actuating the mechanical structure in this way, the emitting cavity 106 is also tuned and stabilised at the single photon emission wavelength due to the two cavities 106, 110 being supported by the same mechanical structure. Thus, in addition to maintaining the fundamental mode of the locking cavity 110 on resonance with the locking frequency of the locking laser, the fundamental mode of the emitter cavity 106 is maintained on resonance with the single photon emission frequency of the single photon emitter material 112. Whilst the actuator 114 may directly control the locking reflective surface 108 and may only control the emitting reflective surface 104 through the mechanical coupling between the emitting reflective surface 104 and the locking reflective surface 108, the actuator is illustrated in FIG. 1 as being connected to both reflective surfaces to illustrate that the actuator 114 controls both reflective surfaces.

The emitting reflective surface 104 and locking reflective surface 108 are mechanically coupled such that small dimensional changes in the cavity such as changes in cavity length occurring in the emitting cavity 106 also occurs in the locking cavity 110. Moreover, due to the mechanical coupling, tuning the geometry of the locking cavity 110 to counteract these small changes such that the locking cavity 110 is on resonance with the locking laser to lock the locking cavity to the locking laser also tunes and stabilises the emitting cavity 106 at the single photon emission wavelength. The locking cavity 110 may be laterally spaced and substantially axially aligned with the emitting cavity 106 such that the cavities are substantially parallel and therefore the adjustment of the length of the locking cavity 110 adjusts the length of the emitting cavity 106 by the same amount.

Therefore the addition of the locking cavity 110 mechanically coupled to the emitting cavity 106 effectively tunes the emitting cavity 106 to stay on resonance with the single photon emitter material 112 with reduced interference between the light from the locking laser and the photons emitted from the single photon emitter material 112. Thus, the emitter cavity 106 can be actively tuned to maintain the single photon emission output without reducing the power of the single photon emission output as a result of significant interference. The addition of the locking cavity 110 to provide a dual cavity locking protocol stabilises the frequency of the photons emitted from the emitting cavity 106, overcoming emitting cavity 106 instability and the complications associated with transmitting light from a locking laser into an emitting cavity, as explained above. Moreover, as the locking laser and locking cavity 110 are decoupled from the emitting cavity 106, the locking laser can be shared across multiple apparatuses which facilitates multi-device frequency matching. The locking laser may be further locked to a global reference laser in order to facilitate multi-device synchronisation. Where an excitation laser is used, this may also be shared across multiple apparatuses.

The initial tuning of the locking cavity 110, and consequently the emitter cavity 106, may occur during fabrication, in which a larger bulk movement of the spacing between the reflective surfaces of the cavities can be achieved during assembly, such that a tuning of the emitter cavity 106 and the locking cavity 110 can be found and fixed in place such that, in use, tuning the locking cavity 110 to the locking laser wavelength brings the emitter cavity 106 on resonance with the peak emission wavelength of the single photon emitter material 112. Then, finer tuning of the apparatus 100 using the actuator 114 may be performed, for example, during testing, also referred to as alignment, where the laser has already been locked but has drifted and the tuning that occurs at this stage is normally fine tuning and may include tilting the locking cavity 110 (axial alignment) in addition to lateral alignment.

The locking cavity 110 may be optimised for use as a locking cavity using the Pound Drever Hall (PDH) technique. The PDH technique uses phase modulated light from the locking laser, received in the locking cavity 110. The phase of the portion of light from the locking laser that is output from the locking cavity 110 is detected, for example by homodyne detection, to determine the error and the resonant wavelength of the locking cavity 110, compared to the wavelength of the stable locking laser, and the detected error us used to feedback to the actuator 114 to correct the length of the locking cavity 110 to be on resonance with the locking laser again. Thus, the PDH technique enables the locking of a cavity to a laser. It enables the measurement of small changes in the length of the locking cavity 110 with extremely high precision. Any small changes in the length of the locking cavity 110 cause the locking cavity to drift out of resonance with the stable wavelength of the light from the locking laser and so cause a change, for example an increase, in the phase error signal detected from the light output from the locking cavity 114 by homodyne detection. By detecting the phase error of the light output from the locking cavity 110, the small change in the length of the locking cavity 110 can be detected and, based on this, the actuator 114 can then adjust the length of the locking cavity to compensate for the small change so that the locking cavity 110 is on resonance with the locking laser, known as locking the locking cavity 110 to the locking laser.

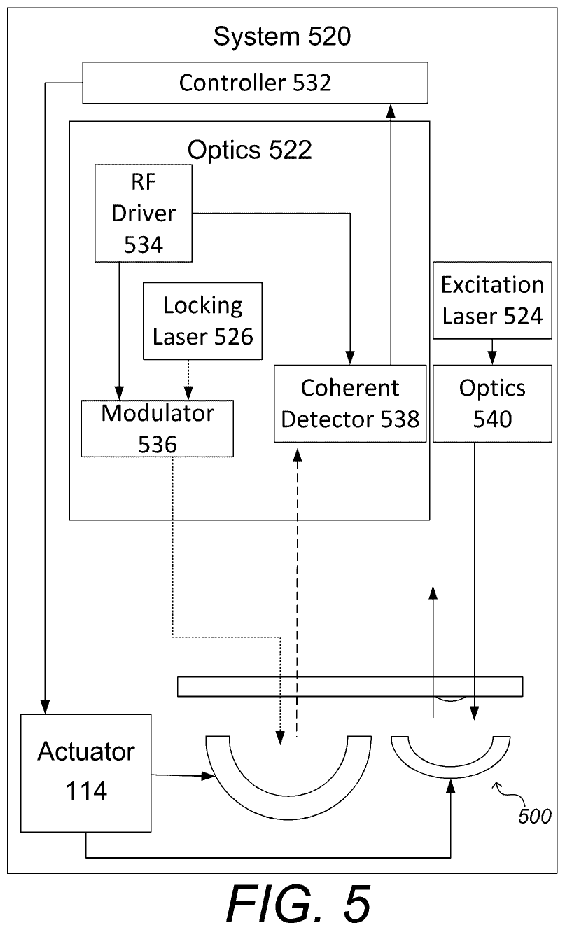

The direction in which the locking wavelength is off resonance with the locking cavity 110, and so the direction in which to adjust the length of the locking cavity 110 (whether to increase or decrease the length) is also determined from the detection of the light output from the locking cavity 110. In the PDH technique, as the light from the locking laser is phase modulated before it enters the locking cavity 110, the direction in which the locking wavelength is off resonance with the locking cavity 110 can be determined by the light output from the locking cavity 110. This is because it can be determined from the light output from the locking cavity 110 whether the laser frequency is above or below resonance by whether the signal from the homodyne detection indicates the reflected signal is out of phase by a positive amount, ahead of the phase modulated input locking laser, or by a negative amount, behind the phase modulated input locking laser. Using the PDH technique is advantageous as the direction of mismatch in addition to the size of mismatch between the laser frequency and resonance of the locking cavity 110 can be detected and corrected. Also, it is fairly straightforward to set up and provides a stable source of an error signal that does not vary with intensity fluctuations in the locking laser. Components to implement the PDH technique are described below in relation to FIG. 5.

In addition to tuning the single photon output using the cavity locking mechanism provided by the locking cavity 110 and emitting cavity 106 of the apparatus 100 of FIG. 1, as described above, the single photon emitting material 112 may be tuned inside the emitting cavity. That is, the zero phonon line emission frequency of the single photon emitting material 112 may be electrically tuned by stabilising the optical transition directly. The electrical tuning by the Stark effect of the strengths of both cycling and spin-altering transitions enables the stabilisation of the zero phonon line emission frequency. Electrical tuning of the single photon emitting material 112 can be achieved by depositing multiple electrodes around the single photon emitting material and applying a bias between the electrodes which creates an electric field through the material and tunes the material. The use of multiple electrodes ensures fine control over the orientation of the electric field to enable optimal alignment between the electric field and the emitter dipole orientation for improved tuning capability. Utilising both methods of tuning improves the tuning further to increase the number of single photons released at the single photon emission frequency.

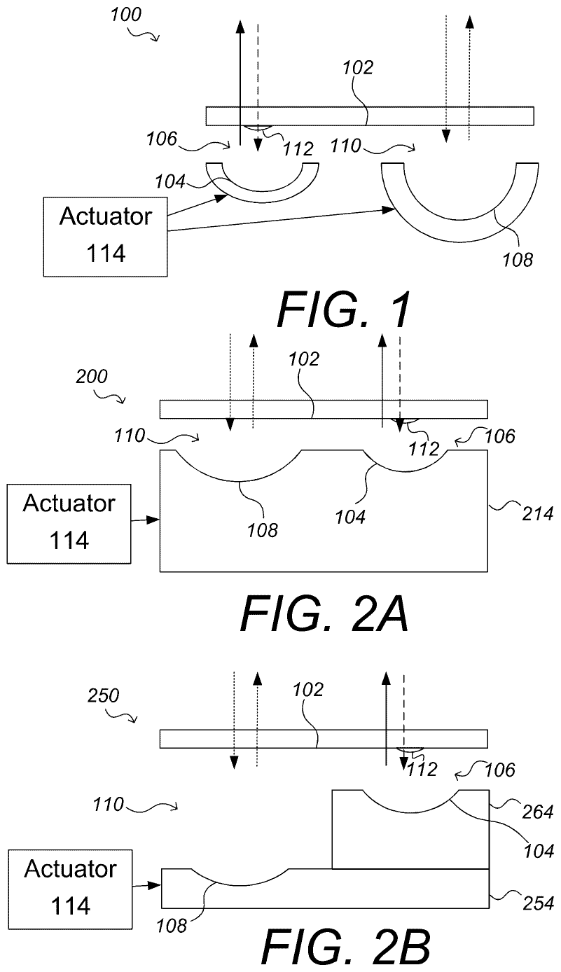

FIG. 2A shows a first embodiment of an apparatus for generating single photons in accordance with aspects of the present disclosure. The apparatus 200 illustrated in FIG. 2A is an example of the apparatus 100 of FIG. 1, and so like reference numbers apply to like features, a detailed explanation of which may be provided above in relation to FIG. 1. The apparatus 200 comprises a substrate 214 and the locking reflective surface 108 and emitting reflective surface 104 are provided on the substrate 214, formed therein for example by focused ion beam milling or any other suitable means such as CO2 laser processing. The locking recess formed in the locking reflective surface 108 forms the locking cavity 110 and the emitting recess formed in the emitting reflective surface 104 forms the emitting cavity 106. Thus, any movement of the substrate 214 by an actuator 114 (not shown) relative to the first reflective surface 102 would tune both the locking cavity 110 and the emitting cavity 106. The locking recess and emitting recess may have different depths (due to different FIB milling amounts) such that the length of the locking cavity 110 differs to the length of the emitting cavity 106, allowing the locking laser to have a different resonant frequency to the peak emission frequency of the single photon emitting material 112 enhanced by the emitting cavity 106. Alternatively, the lengths of the locking cavity 110 and emitting cavity 106 may be substantially the same.

In an example implementation of the apparatus 200 of FIG. 2A, the single photon emitting material 112 may have a peak emission wavelength of 575 nm and the locking frequency of the locking laser may be 561 nm. Moreover the cavity length may be similar. Cavity linewidth is determined by the cavity quality factor Q= [symbol] q where [symbol] is finesse. The cavity quality factor Q is in turn determined by the cavity length L and mirror reflectivity R. In an example, both cavities have a cavity length of 1-2 μm, leading to a finesse [symbol] of approximately 500-1000 and a quality factor of approximately 3000 (with q being 5.5). For the locking cavity, the linewidth may therefore be approximately 158 GHz. Where the locking recess 110 and emitting recess 106 are formed in the same substrate, the recesses, and consequently the cavities, may be arranged as a cluster on a substate, allowing an appropriate locking cavity to be selected.

FIG. 2B shows a second embodiment of an apparatus for generating single photons in accordance with aspects of the present disclosure. The apparatus 250 illustrated in FIG. 2B is an example of the apparatus 100 of FIG. 1, and so like reference numbers apply to like features, a detailed explanation of which may be provided above in relation to FIG. 1. The apparatus 250 comprises a substrate 254 and the locking reflective surface 108 is provided on the substrate 254, the locking recess formed in the locking reflective surface 108 forming the locking cavity 110. The apparatus 250 comprises a further substrate 264 in addition to the substrate 254, supported thereby and mechanically coupled thereto. The emitting reflective surface 104 is provided on the further substrate 264, the emitting recess formed in the emitting reflective surface 104 forming the emitting cavity 106. The further substrate 264 is mechanically joined to the substrate 254 and located between the substrate 254 and the first reflective surface 102. For example, during fabrication, the further substrate 264 may be deposited onto the substrate 254. Alternatively, the shape provided by the substrate 254 and the further substrate 264 may be provided in a unitary body by etching a step in the body to create the difference in height relative to the first reflective surface 102.

As the substrates in the FIG. 2B embodiment are mechanically coupled, the locking reflective surface 108 and emitting reflective surface 104 are also mechanically coupled. Thus, any movement of the substrate 254 by an actuator 114 (not shown) relative to the first reflective surface 102 would also move the further substrate 264 and so would tune both the locking cavity 110 and the emitting cavity 106 together. Moreover, any movement of the further substrate 264 relative to the first reflective surface 102 by the actuator 114 would cause the same.

In the apparatus 250 of FIG. 2B, the single photon emission output may have a wavelength of above 560 nm and the locking frequency of the locking laser may be 633 nm. The locking cavity may have a much longer length than the emitting cavity to provide a more efficient and simple implementation of the PDH technique.

To effectively implement PDH, the phase modulation frequency should be substantially larger than the laser linewidth and the cavity linewidth. In the apparatus 200 of FIG. 2A, an example linewidth of the locking cavity was approximately 158 GHz, however such a high linewidth would require very high frequency phase modulation, of many hundreds of GHz or even THz, and so would be too difficult to achieve using standard phase modulation electronics. Therefore, by the arrangement shown in FIG. 2B, the locking cavity linewidth can be reduced to a level at which a lower phase modulation frequency, in the GHz range, can be used to effectively implement a PDH cavity locking scheme. As mentioned above, the cavity linewidth is determined by the cavity quality factor Q= [symbol] q and the cavity quality factor Q is determined in turn by the cavity length L and mirror reflectivity R. Mirror reflectivity R is determined to be 99.9% for other reasons, as set out below, and so, to reduce the locking cavity linewidth, the locking cavity length L can be increased. The provision of the locking reflective surface 108 and emitting reflective surface 104 on substrates provided at different heights relative to the first reflective surface 102 enables the length of the locking cavity 110 to be longer than the length of the emitting cavity 106. This allows for the length of the locking cavity 110 to be increased in size, without requiring the length of the emitting cavity 106 to be increased in size, which allows the locking cavity linewidth to be reduced, such that PDH can be implemented with standard phase modulation electronics.

As mentioned in relation to FIG. 1, the first reflective surface 102 has a reflection coefficient in the wavelength of interest in the region of 99.9%. It is advantageous for the emitting cavity 106 to have an asymmetric reflectivity setup to bias the emission of single photons towards the first reflective surface 102 such that most photons transmit through the planar mirror. To provide such a setup, the emitting reflective surface 104 may have a reflection coefficient in the wavelength of interest in the region of 99.99%, different to that of the first reflective surface 102. Due to ease of setup, it is advantageous for the locking cavity 110 to have a symmetric reflectivity setup and so the locking reflective surface 108 may have a reflection coefficient in the wavelength of interest in the region of 99.9%, the same as the first reflective surface 102. The provision of the locking reflective surface 108 and emitting reflective surface 104 on different substrates, as illustrated in FIG. 2B, enables the surfaces to have different reflectivities and thus allows differential mirroring. The different reflectivities may be provided by different coatings on the surfaces of the substrates.

In an example implementation of the apparatus 250 of FIG. 2B, the emitting cavity may still have a length of 1-2 μm, as discussed above in relation to FIG. 2A, but the locking cavity may have a larger length of 500 μm. A cavity length, L, of 500 μm would result in q being 1580 (using the equation q=2 nL/λ) and with both mirrors having a reflectivity of 99.9% this would result in a finesse of approximately 3000 and a quality factor of 7.9×10\hat{ }5. The locking cavity linewidth Δv would therefore be 600 MHz (using the equation Δv=v/Q). As phase modulation needs to be substantially greater than the linewidth, this would only require a few GHz for phase modulation, which can be easily implemented using for example an electro optic modulator (EOM) having a lithium niobate or MgO:LN-type crystal. Moreover, when q=1,782, the free spectral range is 0.3 nm so approximately 300 GHz, which provides a high density of fundamental modes, which is beneficial for finding a mode to lock to. The apparatus 250 of FIG. 2B is therefore advantageous because it provides greater dimensional flexibility such as enabling a larger locking cavity length and as such the tuning of the apparatus is simpler and less complex to implement due to requiring less complex phase modulation to implement PDH.

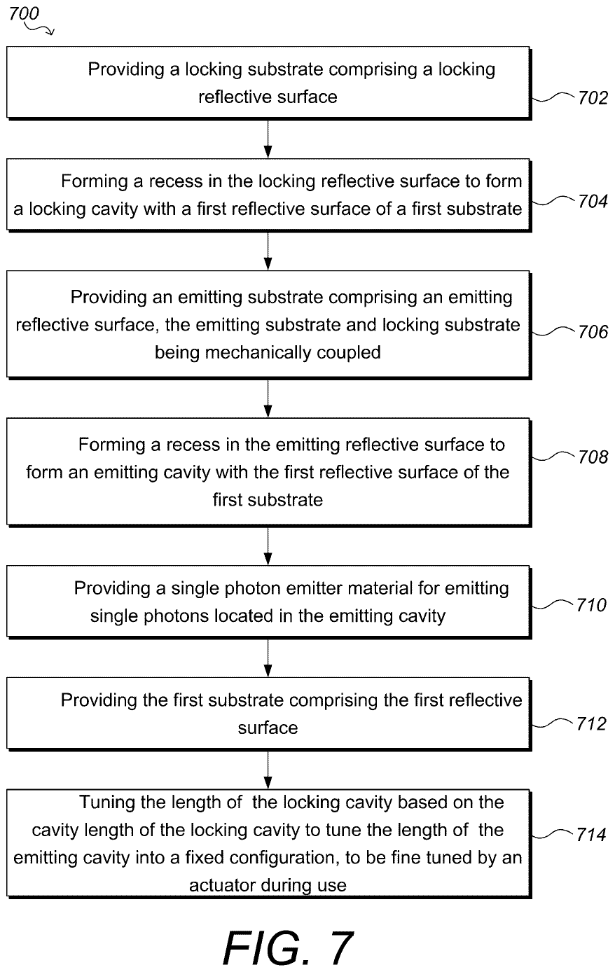

Whilst the recesses in FIGS. 2A and 2B are illustrated as recesses within substrates, for example, formed by focused ion beam, as discussed in relation to FIG. 7, other recesses are envisaged.

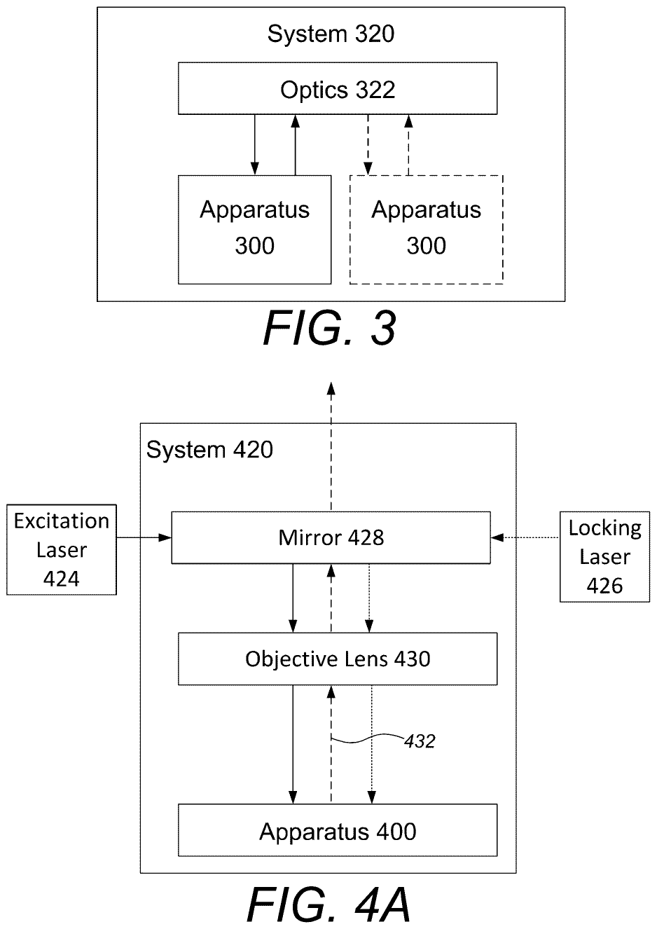

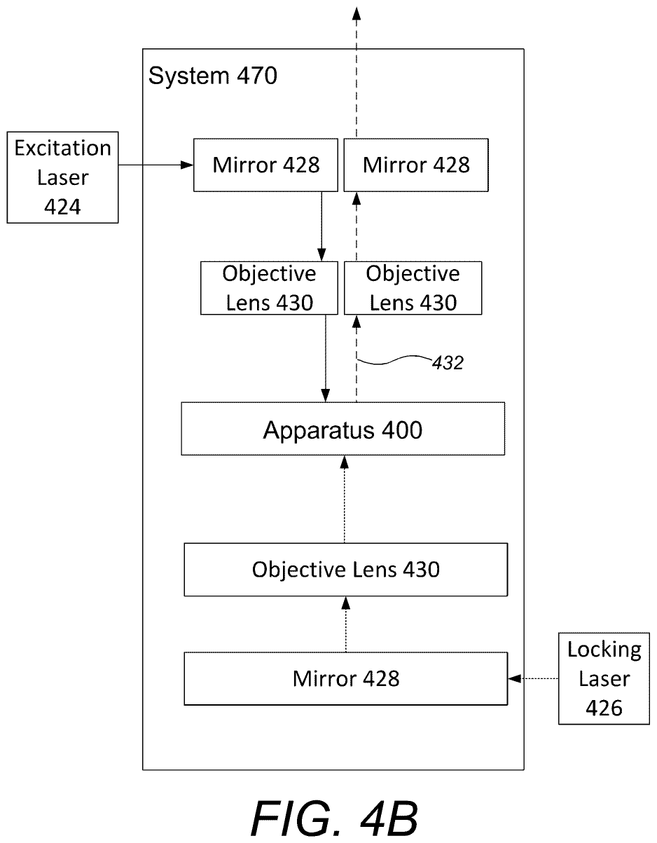

FIG. 3 shows a schematic illustration of an embodiment of a system 320 for use in generating single photons in accordance with aspects of the present disclosure. The system 320 comprises one or more apparatus 300 for generating single photons. The apparatus 300 is an example of the apparatus 100 of FIG. 1. The apparatus 300 may be the apparatus 200 of FIG. 2A or the apparatus 250 of FIG. 2B. The system 320 further comprises optics 322 for transmitting light into the locking cavity of the apparatus. Examples of the system 320 are provided in FIGS. 4 and 5.

The optics 322 may comprise a locking laser for generating light for transmission into the locking cavity of the apparatus 300. The light generated by the locking laser may be of substantially a single wavelength. The single wavelength of the locking laser may be different to that of the single photon emission wavelength to reduce interference. The optics 322 may further comprise any guiding means to guide the light generated by the locking laser into the locking cavity of the apparatus 300. Due to the apparatus 300 comprising a locking laser and locking cavity decoupled from the emitting cavity, as discussed in relation to FIG. 1, the locking laser can be shared across multiple apparatus 300. As such, the optics 322 providing the light generated by the locking laser can also be shared across multiple apparatus 300, as illustrated in FIG. 3. Sharing the optics 322 between multiple apparatus 300 reduces the size and power consumption of the system 320 and provides a compact system for generating single photons. Further, it allows the single photon emitters in each of the plural apparatuses 300 to be tuned and held stable at a frequency determined by a common stable locking laser.

FIG. 4A shows a further schematic illustration of another embodiment of a system for generating single photons in accordance with aspects of the present disclosure. The system 420 of FIG. 4A is an example of the system 320 of FIG. 3. The system 420 includes an apparatus 400, which is an example of the apparatus 100 of FIG. 1 and may be the apparatus 200 of FIG. 2A or the apparatus 250 of FIG. 2B. The system 420 may also include further apparatus 400 (not shown). The system also includes optics such as a mirror 428 and an objective lens 430. The mirror 428 may be a dichroic or fibre based mirror. The system 420 is connected to a locking laser 426 that is to transmit light into the system 420 and the mirror 428 and objective lens 430 direct the light received by the locking laser 426 into the locking cavity of the apparatus 400. The system 420 is also connected to an excitation laser 424 for generating light for transmission into the emitting cavity 106 of the apparatus 400 to optically excite the single photon emitter material 112. The excitation laser 424 is to transmit light into the system 420 and the mirror 428 and objective lens 430 direct the light received by the excitation laser 424 into the emitting cavity 106 of the apparatus 400. The single photons output from the apparatus 400, as indicated by arrow 432, are also directed by the mirror 428 and objective lens 430. In the system 420 of FIG. 4A, the light output from the locking laser 426 and excitation laser 424 and the single photons output from the apparatus 400 share the mirror 428 and objective lens 430. Whilst the locking laser 426 and excitation laser 424 are illustrated as being separate from the system 420, they may also form part of the system 420. Moreover, one laser may form the locking laser 426 and excitation laser 424. The system 420 may include further optics such as polarisation optics.

FIG. 4B shows a further schematic illustration of another embodiment of a system for generating single photons in accordance with aspects of the present disclosure. The system 470 of FIG. 4B comprises the same components as the system 420 of FIG. 4A, however the components are arranged differently. The system 470 of FIG. 4B further comprises a plurality of mirrors 428, and objective lenses 430. This is because, in the system 470 of FIG. 4B, the outputs from the locking laser 426 and excitation laser 424 do not share the mirror 428 and objective lens 430 but rather the locking laser 426 is fed from a different location. For example, the locking laser 426 may be fed into the side of the locking recess. The use of different objective lenses 430 for the different lasers is advantageous as the optical alignment of the excitation laser 424 and locking laser 426 is then decoupled and can be optimized separately. Moreover there may be a further mirror 428 and objective lens 430 for receiving the single photons output from the apparatus 400, as indicated by arrow 432, such that the single photons can be optimized separately. Alternatively, the light output from the excitation laser 424 and the single photons output from the apparatus 400 may share a mirror 428 and objective lens 430.

FIG. 5 shows a further schematic illustration of another embodiment of a system for generating single photons in accordance with aspects of the present disclosure. The system 520 of FIG. 5 is an example of the system 320 of FIG. 3 and the system 420 of FIG. 4. The system 520 includes an apparatus 500, which is an example of the apparatus 100 of FIG. 1 and may be the apparatus 200 of FIG. 2A or the apparatus 250 of FIG. 2B. The system 520 may also include further apparatus 500 (not shown). The cavities of the apparatus 500 are illustrated to show the path of the light transmitted to and received from the cavities.

The system 520 comprises a controller 532, an excitation laser 524 and optics 540 to transmit the light from the excitation laser 524 into the emitting cavity 106 of the apparatus 500. The system 520 further comprises optics 522 to transmit the light from the locking laser into and receive the light from the locking cavity 110. The optics 522 includes an RF driver 524, a locking laser 526, a modulator 536 and a coherent detector 526. The locking laser 526 is for generating light for transmission into the locking cavity 110 of the apparatus 500 and the modulator 536, such as an electro-optic modulator or a Pockels cell, is to modulate the phase or frequency of the light generated by the locking laser 526 before it is transmitted into the locking cavity 110 of the apparatus 500. The phase modulator 536 enables the Pound Drever Hall Technique to be utilised to lock the locking cavity 110. The modulator 536 may be an electro optic modulator. A local oscillator, such as an RF driver 534, is coupled to the electro optic modulator and configured to output a modulation signal to drive the modulator 536 to modulate the phase of the locking laser 526 at a phase modulation frequency substantially greater than the linewidth of the locking cavity. An optimal phase modulation frequency is 1 GHz or higher. FIG. 5 illustrates that light from the locking laser 526 is transmitted into the locking cavity 110 of the apparatus 500 from the top of the apparatus 500 through the first reflective surface 102. However, the locking laser 526 may instead be configured such that light from the locking laser 526 is transmitted into the locking cavity 110 of the apparatus 500 from the bottom of the apparatus 500 through the locking reflective surface 108.

When the locking cavity receives the phase modulated light from the locking laser, a portion of the light is either reflected or transmitted from the locking cavity 110 based on the difference between the resonance of the locking cavity 110 and the locking frequency of the locking laser 526. This light output from the locking cavity 110 is detected by a photodetector, such as a coherent detector 538, which provides a feedback signal to the controller 532 corresponding to the light output from the locking cavity 110. The feedback signal may be based on the phase of the light output from the locking cavity 110. The coherent detector 538 may generate the feedback signal by mixing the detected light signal with the modulation signal from the RF driver, using homodyne detection to reveal a phase difference, which is indicative of a phase error and is used as the feedback signal.

Based on the feedback signal, the controller 532 determines the amount and direction of adjustment of the locking cavity and outputs an error signal to the actuator 114 to control the actuator 114 to make adjustments to the length of the locking cavity 110 to lock the locking cavity to the locking laser. The controller 532 may be a feedback controller such as a PID controller. By tuning the locking cavity, the optics 522 and actuator 114 also tunes the emitting cavity as the locking cavity and emitting cavity are mechanically coupled such that any changes to the length of the optical cavity also change the length of the emitting cavity. Thus, by locking the locking cavity to the locking laser by removing any small changes to the length of the locking cavity, these small changes are also removed from the length of the emitting cavity. Where the emitting cavity was initially on resonance with the single photon emission wavelength, the removal of these small changes from the length of the emitting cavity tunes and stabilises the emitting cavity at the single photon emission wavelength. This provides a single photon emitter with long term stability.

The optics 522 may comprise a mixer (not shown) to sum the input from the RF driver, which may be phase shifted, and the coherent detector 538 and to pass the resultant signal, the feedback signal, to the controller 532 or straight to the actuator 114 to adjust the length of the laser cavity. Before the resultant signal is passed to the controller 532 it may be filtered by a low pass filter (not shown).

The excitation laser 524 is for generating light for transmission into the emitting cavity 106 of the apparatus 500 and the optics 540 is to guide the light generated by the excitation laser 524 into the emitting cavity 106 of the apparatus 500. The excitation laser 524 may provide phase modulated pulses of light having a wavelength of, for example, 532 nm to excite the single photon emitting material 112. In response to being excited by the light from the excitation laser 524, the single photon emitting material 112 emits single photons with a higher quantum efficiency due to enhancement by the emitter cavity, and having a stable wavelength due to the dual cavity locking arrangement, with noise from the phonon sideband being suppressed.

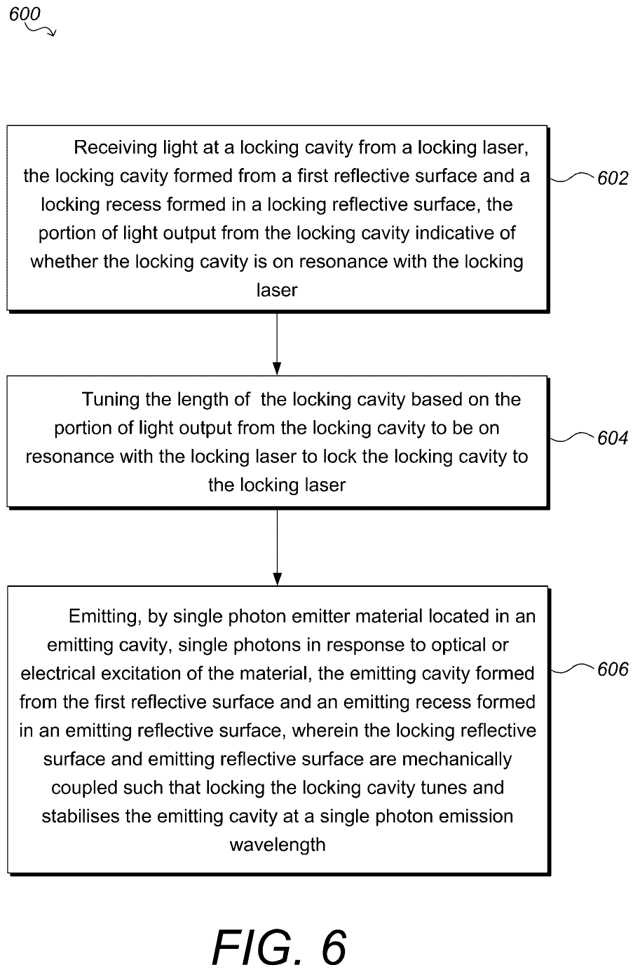

FIG. 6 shows a method 600 for generating single photons in accordance with aspects of the present disclosure. The method 600 may be performed by the apparatus 100 of FIG. 1, the apparatus 200 of FIG. 2A or the apparatus 250 of FIG. 2B. The method 600 may be performed during manufacture of the apparatus and/or during use of the apparatus. The method 600 comprises receiving 602 light at a locking cavity 110 from a locking laser, the locking cavity 110 formed from a first reflective surface 102 and a locking recess formed in a locking reflective surface 108, the portion of light output from the locking cavity 110 indicative of whether the locking cavity 110 is on resonance with the locking laser.

The method further comprises tuning 604 the length of the locking cavity 110 based on the portion of light output from the locking cavity 110 to be on resonance with the locking laser to lock the locking cavity to the locking laser. The tuning of the length may be performed by an actuator 114. The method may further comprise receiving light at an emitting cavity 106 from an excitation laser to optically stimulate the single photon emitter material 112 to emit photons. The method further comprises emitting 606, by single photon emitter material 112 located in an emitting cavity 106, single photons in response to optical or electrical excitation of the material 112, the emitting cavity 106 formed from the first reflective surface 102 and an emitting recess formed in an emitting reflective surface 104, wherein the locking reflective surface 108 and emitting reflective surface 104 are mechanically coupled such that locking the locking cavity 110 tunes and stabilises the emitting cavity 106 at a single photon emission wavelength.

FIG. 7 shows a method 700 of manufacturing an apparatus for generating single photons in accordance with aspects of the present disclosure. The method 600 may be to manufacture the apparatus 100 of FIG. 1 or the apparatus 250 of FIG. 2B. The method 700 comprises providing 702 a locking substrate comprising a locking reflective surface 108. The locking substrate may be made of any suitable material, for example, the substrate may be a borosilicate glass substrate. The method 700 further comprises forming 704 a recess in the locking reflective surface 108 to form a locking cavity 110 with a first reflective surface 102 of a first substrate. The recess may be formed by any suitable technique such as CO2 laser processing or FIB milling. Forming the recess using FIB milling provides a recess having a small radius of accurate and precise curvature. During the milling process, I₂ gas may be added to minimize the surface roughness. The method 700 further comprises providing 706 an emitting substrate comprising an emitting reflective surface 104, the emitting substrate and locking substrate being mechanically coupled. For example, the emitting substrate may be deposited onto the locking substrate using a mask. The method 700 further comprises forming 708 a recess in the emitting reflective surface 104 to form an emitting cavity 106 with the first reflective surface 102 of the first substrate. This recess may also be formed by FIB milling. Such FIB milling provides an ultra-small mode volume on the order of λ³.

The method 700 further comprises providing 710 a single photon emitter material 112 for emitting single photons located in the emitting cavity 106. The single photon emitter material 112 may be provided at the focal point of the emitting cavity 106. The single photon emitter material 112 may be treated, for example, using plasma, UV Ozone exposure, e-beam irradiation or ion-beam irradiation. The plasma treatment may use plasma sources such as oxygen, hydrogen or methane. In an example, where the single photon emitter material 112 is hBN flakes, these may be treated with oxygen plasma followed by rapid thermal annealing before being provided in the emitting cavity 106. The single photon emitter material 112 may be provided on the first reflective surface 102 or on the emitting reflective surface 104 in the emitting cavity 106. The method 700 further comprises providing 712 the first substrate comprising the first reflective surface 102. To form the emitting cavity 106, a spacer may be formed on the emitting substrate and the first substrate may be formed on the spacer. For example, the spacer may be deposited followed by the first substrate.

The method 700 further comprises tuning 714 the length of the locking cavity 110 based on the cavity length of the locking cavity 110 to tune the length of the emitting cavity 106 into a fixed configuration, to be fine-tuned by an actuator during use. Thus, as mentioned in relation to FIG. 1, the actuator 114 may be utilised to coarsely tune the locking cavity 110 during manufacture and may subsequently be used to finely tune the locking cavity 110 during testing/alignment. In an example, the method 700 may further comprise, before providing the first substrate 712, instead of or in addition to the spacer, providing a tuneable polymer spacer, wherein the tuneable polymer spacer is to be connected to the actuator 114 and receive a tuning force from the actuator 114 to compress the polymer and thus change the length of the locking cavity. Providing a tuneable polymer spacer enables in situ tuning of the cavity length. An example polymer that is capable of reversible deformation is polydimethylsiloxane (PDMS). The tuneable polymer spacer may be etched around the emitting cavity 106 to prevent influence of the spacer on single photon emission by the single photon emitter material 112.

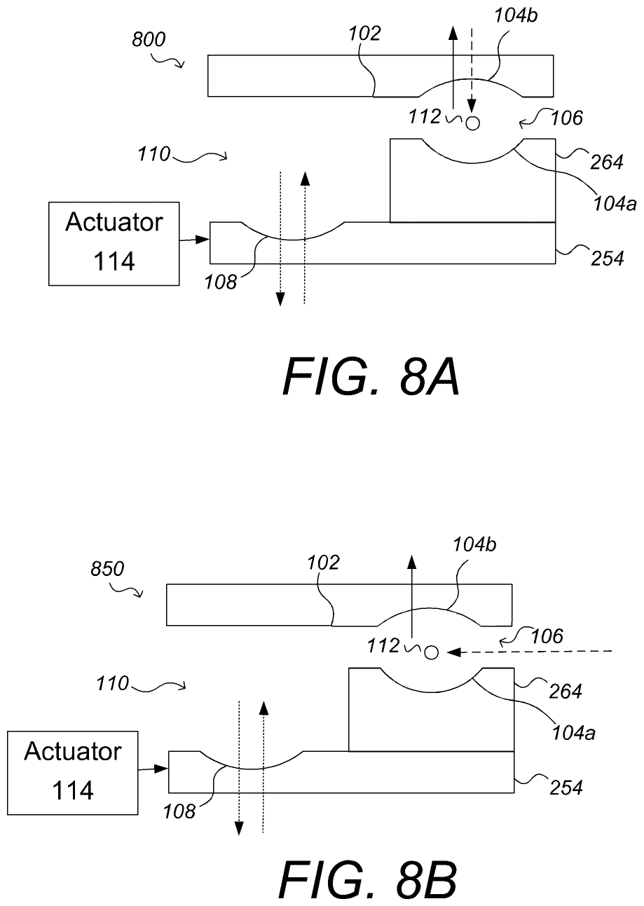

FIG. 8A shows a third embodiment of an apparatus for generating single photons in accordance with aspects of the present disclosure. The apparatus 800 illustrated in FIG. 8A is an example of the apparatus 100 of FIG. 1, and so like reference numbers apply to like features, a detailed explanation of which may be provided above in relation to FIG. 1. The structure of the apparatus 800 is similar to that of the second embodiment shown in FIG. 2B, with the difference being that the single photon emitting material 112 is a quantum object such as a trapped ion or neutral atom in a physical qubit of a quantum computer. Here, the quantum object is suspended in the emitter cavity 106, and rather than being plano-concave in form, the emitter cavity 106 is concave-concave, formed between, an emitter recess 104a and a complementary emitter recess 104b formed in the first reflective surface 102. Providing a concave-concave cavity in this way allows the trapped ion or neutral atom providing the single photon emitter material 112 to be located in the middle of the cavity at the cavity waist where the enhancement effect is greatest. In this respect, the tuned emitter cavity 106 provides a light-matter interface for interacting with the quantum object, and enhancing single photon emission therefrom after stimulation by the excitation laser (as indicated by the broken arrow) causing the optical transition. This facilitates photonic manipulation and control of the qubit, for example, to aid the performance of qubit gate operations in the quantum computer. In the third embodiment, the locking laser (as indicated by the dotted arrows) back-illuminates the locking cavity 110.

FIG. 8B shows a fourth embodiment of an apparatus for generating single photons in accordance with aspects of the present disclosure. The apparatus 850 illustrated in FIG. 8B is an example of the apparatus 100 of FIG. 1 and in particular corresponds to apparatus 800 shown in FIG. 8A, and so like reference numbers apply to like features, a detailed explanation of which may be provided above in relation to FIG. 1. In the FIG. 8B embodiment, the arrangement is similar to that of the embodiment shown in FIG. 8A, with the difference that the excitation laser illuminates the apparatus 850 and enters the emitter cavity 106 from the side as shown by the broken arrow. This arrangement facilitates interaction with the trapped ion or neutral atom providing the single photon emitter material 112 in the middle of the cavity, and removes the excitation laser from the optical path of the single photon emission.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed. The claims should not be construed to cover merely the foregoing embodiments, but also any embodiments which fall within the scope of the claims.

1. An apparatus for providing a light-matter interface for enhancing transitions that generate single photons, the apparatus comprising:
a first reflective surface;
a locking recess formed in a locking reflective surface, the first reflective surface and locking recess forming a locking cavity to receive light from a locking laser, the portion of light output from the locking cavity indicative of whether the locking cavity is on resonance with the locking laser;
an emitting recess formed in an emitting reflective surface, the first reflective surface and emitting recess forming an emitting cavity to receive photons from a single photon emitter material;
the single photon emitter material located in the emitting cavity to emit single photons in response to optical or electrical excitation of the material; and
an actuator to tune the length of the locking cavity based on the portion of light output from the locking cavity to be on resonance with the locking laser to lock the locking cavity to the locking laser,
wherein the locking reflective surface and emitting reflective surface are mechanically coupled such that locking the locking cavity tunes and stabilises the emitting cavity at a single photon emission wavelength.

2. (canceled)

3. The apparatus according to claim 1, wherein the locking reflective surface and emitting reflective surface are mechanically supported by the same substrate.

4. The apparatus according to claim 1, wherein the portion of light output from the locking cavity is the portion of light reflected and/or transmitted from the locking cavity, and wherein the emitting cavity is configured to receive light from an excitation laser and the single photon emitter material is located to emit single photons in response to the received light from the excitation laser being incident on the material.

5. The apparatus according to claim 1, wherein the locking reflective surface and emitting reflective surface are at different distances from the first reflective surface, such that locking cavity has a different length to the emitting cavity, wherein the locking reflective surface and emitting reflective surface are on different substrates, wherein each of the different substrate comprising the emitting reflective surface is mechanically coupled to the locking reflective surface of the substrate comprising the locking reflective surface.

6. (canceled)

7. (canceled)

8. The apparatus according to claim 1, wherein the emitter cavity and the locking cavity are laterally spaced and substantially axially aligned, and wherein the emitting cavity and the locking cavity operate in different modes and have different resonant wavelengths.

9. The apparatus according to claim 1, wherein the emitting recess and locking recess have different depths.

10. (canceled)

11. The apparatus according to claim 1, wherein the emitting cavity is configured with a length in the range 0.3-10 μm and a line width in the range 10-1000 GHz, and wherein the locking cavity is configured with a length in the range 10-1000 μm and a line width in the range 10-1000 MHz, and wherein the locking cavity and emitting cavity are Fabry-Perot cavities.

12. (canceled)

13. The apparatus according to claim 1, wherein the single photon emitter material is a two-dimensional material having a fluorescent defect or a quantum dot, and wherein the single photon emitter material is to emit single photons at temperatures in the range 0-20° C., and wherein the single photon emitter material comprises hexagonal Boron Nitride, hBN, a trapped ion or neutral atom.

14. (canceled)

15. (canceled)

16. The apparatus according to claim 13, wherein the single photons emitted from the single photon emitter material have a wavelength of approximately 400 nm or above.

17. The apparatus according to claim 1, wherein tuning the length of the locking cavity comprises adjusting the first reflective surface and/or locking reflective surface.

18. The apparatus according to claim 1, wherein the actuator is a piezo actuator, and wherein the actuator is to tune the length of the locking cavity based on the phase of the portion of light output from the locking cavity.

19. (canceled)

20. (canceled)

21. (canceled)

22. A system for providing a light-matter interface for enhancing transitions that generate single photons, the system comprising:
an apparatus comprising:
a first reflective surface,
a locking recess formed in a locking reflective surface, the first reflective surface and locking recess forming a locking cavity to receive light from a locking laser, the portion of light output from the locking cavity indicative of whether the locking cavity is on resonance with the locking laser,
an emitting recess formed in an emitting reflective surface, the first reflective surface and emitting recess forming an emitting cavity to receive photons from a single photon emitter material,
the single photon emitter material located in the emitting cavity to emit single photons in response to optical or electrical excitation of the material, and
an actuator to tune the length of the locking cavity based on the portion of light output from the locking cavity to be on resonance with the locking laser to lock the locking cavity to the locking laser, wherein the portion of light output from the locking cavity is the portion of light reflected and/or transmitted from the locking cavity,
wherein the locking reflective surface and emitting reflective surface are mechanically coupled by the same substrate such that locking the locking cavity tunes and stabilises the emitting cavity at a single photon emission wavelength; and
optics for transmitting light into the locking cavity of the apparatus.

23. A system according to claim 22, wherein the optics comprises a locking laser to generate light for transmission into the locking cavity of the apparatus and light having a wavelength different to that of the single photon emission wavelength.

24. (canceled)

25. The system according to claim 22, the optics further comprising a modulator to modulate the phase of the light generated by the locking laser and transmit the modulated light into the locking cavity of the apparatus, wherein the modulator is an electro optic modulator, the system further comprising an RF driver coupled to the electro optic modulator and configured to output a modulation signal to drive the modulator to modulate the phase of the locking laser at a phase modulation frequency substantially greater than the linewidth of the locking cavity, and wherein the phase modulation frequency is at least 1 GHz.

26. (canceled)

27. (canceled)

28. The system according to claim 25, the optics further comprising a coherent detector to detect the portion of light output from the locking cavity of the apparatus and mix the detected light signal with the modulation signal from the RF driver to output a feedback signal based on the detected portion of light indicative of the drift of the locking cavity from the locking laser.

29. The system according to claim 22, further comprising a controller configured to receive the feedback signal and output an error signal to the actuator of the apparatus based on the feedback signal, the actuator to tune the length of the locking cavity based on the error signal to maintain the locking cavity on resonance with the locking laser, wherein the controller is to output the error signal to the actuator of the apparatus based on the phase of the detected portion of light output from the locking cavity, and wherein the controller a proportional integral derivative, PID, controller.

30. (canceled)

31. The system according to claim 22, wherein the system is configured to optimize the locking cavity using a Pound Drever Hall technique.

32. (canceled)

33. The system according to claim 22, wherein a pulsed excitation laser and optics are further configured to direct light from the pulsed excitation laser to illuminate the single photon emitter material in the emitter cavity to trigger the emission of single photons at the fixed single photon emission frequency.

34. The system according to claim 22, the system is further configured to generate single photons, wherein the optics is configured to transmit light into the locking cavities of each of the apparatuses from the same locking laser, and wherein the optics is further configured to transmit light into the emitting cavities of each of the apparatuses from the same pulsed excitation laser, the photon emitter material of each apparatus to emit single photons in response to the received light from the excitation laser being incident on the photon emitter material.

35. (canceled)

36. The system according to claim 34, wherein each of emitter cavities in the each of apparatuses is configured for emitting single photons, and wherein each emitter cavity emits single photons at substantially the same fixed single photon frequency responsive to illumination by an excitation laser.

37. (canceled)

38. (canceled)

39. A method for generating single photons, the method comprising:
receiving light at a locking cavity from a locking laser, the locking cavity formed from a first reflective surface and a locking recess formed in a locking reflective surface, the portion of light output from the locking cavity indicative of whether the locking cavity is on resonance with the locking laser;
tuning the length of the locking cavity based on the portion of light output from the locking cavity to be on resonance with the locking laser to lock the locking cavity to the locking laser; and
emitting, by single photon emitter material located in an emitting cavity, single photons in response to optical or electrical excitation of the material, the emitting cavity formed from the first reflective surface and an emitting recess formed in an emitting reflective surface;
wherein the locking reflective surface and emitting reflective surface are mechanically coupled such that locking the locking cavity tunes and stabilises the emitting cavity at a single photon emission wavelength.
